(19) United States
(12) Patent Application Publication
(10) Pub. No.: US 2026/0037684 A1
(43) Pub. Date: Feb. 5, 2026

(54) DIGITAL TWIN SYSTEM FOR INTEGRATED MONITORING OF DYNAMIC PARAMETERS IN MODULAR CLEANROOM

(71) Applicant: LOCUS CELL CO.,, New Taipei City (TW)

(72) Inventors: Heng-Yu Liu, New Taipei City (TW); Wei-Ting Lin, New Taipei City (TW); Chih Wei Cheng, New Taipei City (TW); Hui-Ling Chen, New Taipei City (TW)

(21) Appl. No.: 19/268,274

(22) Filed: Jul. 14, 2025

Related U.S. Application Data
(60) Provisional application No. 63/677,142, filed on Jul. 30, 2024.

(51) Int. Cl. G06F 30/13

(52) U.S. Cl. CPC G06F 30/13

(57) ABSTRACT

A digital twin system for integrated monitoring of dynamic parameters in a modular cleanroom comprises a 3D model construction module, a sensing data processing module, a digital twin module, and a visual display module. The 3D model construction module is configured to construct a 3D model of the modular cleanroom and the facilities and an equipment arranged therein. The sensing data processing module is configured to receive a plurality of dynamic parameters and generate a sensing parameter dataset. The digital twin module is configured to simulate the modular cleanroom in real time based on the sensing parameter dataset, and to perform a contamination risk prediction and a scheduling suggestion using a machine learning model. The visual display module is configured to present the 3D model, the sensing parameter dataset, a risk prediction result, and a scheduling suggestion plan in a visualized and real-time manner for user monitoring and operation.

The present application is based on, and claims priority from, America provisional patent application number U.S. 63/677,142 filed on 2024 Jul. 30 and the disclosure of which is hereby incorporated by reference herein in its entirety.

### BACKGROUND OF THE INVENTION

### Field of the Invention

The present invention relates to a digital twin system, and in particular to a digital twin system for integrated monitoring of dynamic parameters in a modular cleanroom.

### Description of the Prior Art

In modern biopharmaceutical and cell therapy industries, cell culture processes demand extremely stringent control over sterile environments and standardized operating procedures. To ensure product quality and minimize contamination risks, cell factories commonly adopt cleanroom environments for enclosed operations. Especially during the manufacturing of cell therapies or high-grade formulations, even minimal contamination can result in the rejection of entire batches, leading to substantial losses. Therefore, real-time monitoring, risk alerting, and process optimization within cleanrooms have become critical technological challenges in the fields of intelligent manufacturing and intelligent healthcare. However, current cleanroom monitoring technologies still face numerous limitations and challenges, such as:
1. Excessive reliance on manual inspection for equipment monitoring and management
   Most cleanrooms still rely on manual, periodic inspections to monitor the operating status of equipment (such as incubators, workstations, and air supply systems). This approach lacks real-time awareness of abnormal conditions, making it easy to miss critical warning signals.
2. Static and fragmented information presentation
   Current systems only provide data in tabular formats or single-parameter charts, lacking the capability for holistic spatial visualization. This makes it difficult for operators to grasp the overall system status from a macro perspective.
3. Contamination events often detected only after the fact
   When issues such as pressure imbalance, particle concentration spikes, or cross-contamination occur in the cleanroom, current systems fail to integrate relevant dynamic parameters for timely warning. In most cases, anomalies are only discovered through quality inspection after the process is completed, leading to significant losses.
4. Lack of corresponding data update mechanisms for dynamic changes in modular cleanrooms
   Modular cleanrooms offer the advantages of rapid setup and reconfiguration. However, existing monitoring systems fail to reflect structural changes and updated environmental parameters in real time, resulting in a disconnect between the management system and the physical space.
5. Lack of routing and scheduling simulation
   In application scenarios involving multiple intersecting production lines and diverse operation batches, existing systems are unable to simulate personnel, equipment, and material flow paths or predict associated contamination risks, resulting in insufficient support for overall operation scheduling.

In recent years, to address the aforementioned issues, manufacturing systems have begun adopting digital twin technology to simulate equipment operation and synchronize environmental data, aiming to achieve predictive maintenance and process optimization through virtual-real integration. However, when applied to cleanroom environments, existing digital twin systems still face the following technical gaps:
1. The scope of functionality limited to single-point equipment monitoring
   Most systems only focus on data feedback and basic visualization for individual pieces of equipment, lacking the capability to represent the overall cleanroom spatial structure and operational workflow.
2. The alert logic lack of intelligent processing capabilities
   Existing systems commonly rely on fixed threshold settings for issuing alerts, without utilizing machine learning models to actively predict and dynamically adjust based on historical data, environmental variation trends, and human-machine interaction behaviors.
3. Inability to integrate personnel, equipment, and material flow information
   Cleanroom contamination and production bottlenecks are often related to flow planning. However, existing systems lack cross-module data integration mechanisms, making it difficult to perform cross-analysis of operational flows and optimize spatial layouts.
4. Fragmented system platforms lacking a unified integration architecture
   Monitoring, recording, analysis, and visualization are often handled by separate systems or interfaces, resulting in information silos and the inability to provide integrated decision-making support for supervisors or operators in real time.
5. Insufficient level of automation and high reliance on manual intervention
   At the current stage, digital twins are mostly used as informational reference tools and are not integrated into interactive control loops with automated equipment (such as automatic vehicles or automatic liquid exchange devices). This limitation prevents the realization of highly automated operations and the reduction of human errors.

Therefore, it is necessary to design a digital twin system for integrated monitoring of dynamic parameters in a modular cleanroom that is capable of monitoring dynamic parameters within the modular cleanroom. This system should enable real-time simulation and early warning analysis of the cleanroom's dynamic state, thereby enhancing contamination risk control, equipment maintenance efficiency, and the quality of scheduling decisions.

### SUMMARY OF THE INVENTION

In view of this, the present invention provides a digital twin system for integrated monitoring of dynamic parameters in a modular cleanroom, so as to address the aforementioned conventional problems.

The present invention provides a digital twin system for integrated monitoring of dynamic parameters in a modular cleanroom. The system comprises a 3D model generation module, a sensing data processing module, a digital twin module, and a visual display module. The 3D model generation module is configured to construct a 3D model of the modular cleanroom and a facility and an equipment disposed within the modular cleanroom. The modular cleanroom comprises a plurality of cleanrooms. The sensing data processing module is coupled to the 3D model generation module. The sensing data processing module is configured to receive a plurality of dynamic parameters and generate a sensing parameter dataset. The digital twin module is coupled to both the 3D model generation module and the sensing data processing module. The digital twin module is configured to simulate the modular cleanroom in real time based on the sensing parameter dataset, execute a contamination risk prediction and a scheduling suggestion based on a machine learning model, and accordingly generate a contamination risk prediction result and a scheduling suggestion plan. The visual display module is coupled to the digital twin module. The visual display module is configured to visually present the 3D model of the modular cleanroom, the sensing parameter dataset, the contamination risk prediction result, and the scheduling suggestion plan in a visualized and real-time manner for the user monitoring and operation.

Wherein, the dynamic parameters further comprise a personnel-related parameter, an equipment-related parameter, a material-related parameter, a method-related parameter, and an environment-related parameter.

Wherein, the sensing data processing module further comprises at least one sensor device disposed on at least one of the cleanrooms, the facility, and the equipment, and the sensor device is configured to detect and receive the dynamic parameters in real time.

Wherein, the digital twin module further comprises a data analysis unit. The data analysis unit is configured to generate a contamination risk level prediction result, an equipment maintenance prediction result, and a cleanroom environmental quality variation assessment result based on the sensing parameter dataset and a historical data.

Wherein, the digital twin system for integrated monitoring of dynamic parameters in the modular cleanroom further comprises an alert module. The alert module is coupled to the digital twin module and the visual display module, and is configured to trigger a visual and audio alarm and send a real-time warning to the user via the visual display module along with a maintenance recommendation when any of the contamination risk level prediction result, the equipment maintenance prediction result, and the cleanroom environmental quality variation assessment result generated by the data analysis unit exceeds a predefined threshold.

Wherein, the digital twin system for integrated monitoring of dynamic parameters in the modular cleanroom further comprises a scheduling module. The scheduling module is coupled to the digital twin module, and is configured to perform a task scheduling simulation and optimization for multiple production lines based on an equipment availability, a process sequence, a personnel operation behavior, and a cleanroom reconfiguration status.

Wherein, the digital twin system for integrated monitoring of dynamic parameters in the modular cleanroom further comprises an unmanned vehicle control module. The unmanned vehicle control module is coupled to the digital twin module, and is configured to automatically adjust a travel path of a plurality of unmanned vehicles based on an optimized routing command generated by the digital twin module, so as to avoid a contamination hotspot or a path-overlapping area.

Wherein, the 3D model construction module is further configured to support the reconfiguration of the modular cleanroom space and to simulate a configuration result of the equipment and the facility, as well as a logistics routing schedule result under different combinations.

Wherein, the digital twin system for integrated monitoring of dynamic parameters in the modular cleanroom is applied to a cell factory. Each of cleanrooms in the modular cleanroom comprises a plurality of partition panels. The partition panels are configured for rapid assembly to form an internal space and an external area. Each of the partition panels is a movable panel, and the internal space of each of the cleanrooms is a sealed space maintained under positive pressure and laminar flow to achieve a predefined cleanliness level.

Wherein, when the cell factory schedules a yearly maintenance, a repair and maintenance, or a production process, each of the cleanrooms that is designated from the modular cleanrooms is reconfigured by quickly disassembling each of the movable partition panels based on the yearly maintenance, the repair and maintenance, or the production schedule, so as to comply with the yearly maintenance, the repair and maintenance, or the production schedule.

Compared with prior art, the digital twin system for integrated monitoring of dynamic parameters in the modular cleanroom of the present invention can integrate multi-source sensing parameters related to structure, equipment, personnel, and environment of the modular cleanroom. By utilizing the 3D model and the digital twin technology, the system enables real-time mapping of the operational status of the physical cleanroom and simultaneously constructs a virtual model to perform contamination risk simulation and predictive analysis. The digital twin system for integrated monitoring of dynamic parameters in the modular cleanroom of the present invention receives and integrates multiple environmental and equipment dynamic parameters via the sensing data processing module to establish the sensing parameter dataset. It further employs the data analysis module and the machine learning model to perform equipment anomaly prediction, clean zone quality variation assessment, and operation scheduling suggestions, effectively overcoming the limitations of traditional systems that rely solely on point-based monitoring and post-event alerts.

In addition, the digital twin system for integrated monitoring of dynamic parameters in the modular cleanroom of the present invention further addresses the spatial structure and reconfiguration characteristics of the modular cleanroom. A 3D scene model is established to simulate the assembly configuration of the modular cleanroom and the arrangement of equipment based on production requirements. The system also calculates the routing paths of unmanned vehicles (e.g., automated guided vehicles) and personnel, predicts potential contamination risks in overlapping areas, and provides optimized route and workflow planning suggestions. Users can simultaneously observe the 3D model, contamination risk prediction results, and scheduling suggestions through the interface, and perform remote control operations, thereby reducing manual intervention and response time.

Furthermore, the digital twin system for integrated monitoring of dynamic parameters in the modular cleanroom of the present invention can also establish a contamination risk assessment mechanism across multiple cleanrooms. It simulates operational interleaving scenarios among different production lines to predict the probability of cross-contamination, and adjusts the cleanroom configuration and distribution of production nodes based on the simulation results to improve the overall efficiency of space and equipment utilization. Through continuous data accumulation and optimization of the learning model, the system can progressively enhance the accuracy of contamination warnings and the effectiveness of scheduling suggestions, thereby achieving intelligent, modular, and data-driven integrated management of cleanrooms.

Moreover, the digital twin system for integrated monitoring of dynamic parameters in the modular cleanroom of the present invention can effectively integrate existing Manufacturing Execution Systems (MES), Supervisory Control and Data Acquisition (SCADA) systems, and Enterprise Resource Planning (ERP) systems. Through data exchange interfaces (such as OPC UA and RESTful API) or middleware, data bridging and transformation can be performed to construct a unified data architecture. The digital twin system for integrated monitoring of dynamic parameters in the modular cleanroom can acquire cleanroom environmental control and equipment operation status in real time via sensor devices, and combine this with operational information from the MES and ERP systems. This enables vertical integration to the decision-making level for contamination prediction and dynamic scheduling suggestions, effectively overcoming the limitations of traditional systems in terms of insufficient data integration and poor response timeliness.

Overall, the present invention enables simulation and interactive analysis across multiple cleanroom environments through the digital twin module, significantly enhancing the flexibility of modular usage, operational efficiency, and quality stability. It provides an integrated platform for real-time monitoring, decision-making support, and operational optimization, making it well-suited for advanced manufacturing and cell factory automation. This offers an innovative and forward-looking solution to existing cleanroom management systems.

### BRIEF DESCRIPTION OF THE APPENDED DRAWINGS

Some of the embodiments will be described in detail, with reference to the following figures, wherein like designations denote like members, wherein:

FIG. 1 shows a functional block diagram of a digital twin system for integrated monitoring of dynamic parameters in a modular cleanroom of one embodiment of the present invention.

FIG. 2 shows a functional block diagram of a digital twin system for integrated monitoring of dynamic parameters in a modular cleanroom of another embodiment of the present invention.

FIG. 3 shows a functional block diagram of a digital twin system for integrated monitoring of dynamic parameters in a modular cleanroom of another embodiment of the present invention.

FIG. 4 shows a functional block diagram of a digital twin system for integrated monitoring of dynamic parameters in a modular cleanroom of another embodiment of the present invention.

FIG. 5 shows a functional block diagram of a digital twin system for integrated monitoring of dynamic parameters in a modular cleanroom of another embodiment of the present invention.

FIG. 6 shows a functional block diagram of a digital twin system for integrated monitoring of dynamic parameters in a modular cleanroom of another embodiment of the present invention.

### DETAILED DESCRIPTION OF THE INVENTION

In order to make the advantages, spirit and features of the present invention easier and clearer, it will be detailed and discussed in the following with reference to the embodiments and the accompanying drawings. It is worth noting that the specific embodiments are merely representatives of the embodiments of the present invention. The specific methods, devices, conditions, and materials described herein are not intended to limit the scope of the invention or the embodiments corresponding thereto. Additionally, the components illustrated in the drawings are intended only to indicate relative positions and are not necessarily drawn to scale. The step numbers used in the present invention are for distinguishing between steps only and do not imply any particular execution order unless otherwise stated.

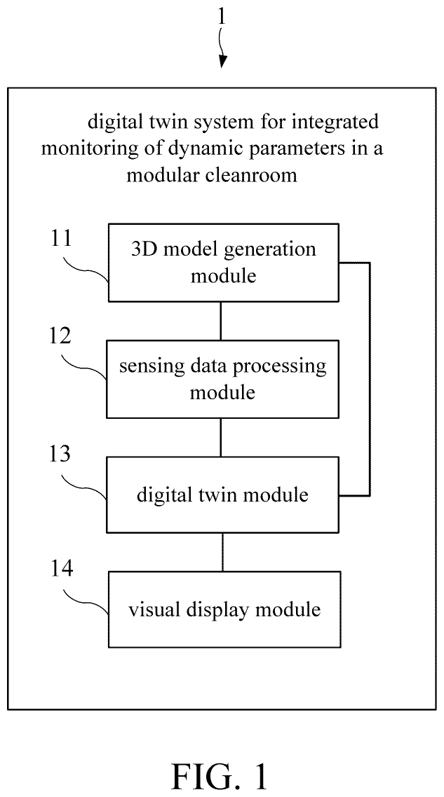

Please refer to FIG. 1, FIG. 1 shows a functional block diagram of a digital twin system for integrated monitoring of dynamic parameters in a modular cleanroom 1 of one embodiment of the present invention. This embodiment provides a digital twin system for integrated monitoring of dynamic parameters in a modular cleanroom 1, which comprises a 3D model generation module 11, a sensing data processing module 12, a digital twin module 13, and a visual display module 14. In this embodiment, the 3D model generation module 11 is configured to construct a 3D model of the modular cleanroom (not shown in figure), and a facility (not shown in figure) and an equipment (not shown in figure) disposed within the modular cleanroom. The modular cleanroom may comprise a plurality of cleanrooms (not shown in figure) and has a detachable structure to accommodate various production configuration needs. The sensing data processing module 12 is coupled to the 3D model generation module 11 and is configured to receive a plurality of dynamic parameters and generate a sensing parameter dataset. The digital twin module 13 is coupled to both the 3D model generation module 11 and the sensing data processing module 12. It is configured to simulate the modular cleanroom in real time based on the sensing parameter dataset, and to execute contamination risk prediction and scheduling suggestions using a machine learning model, thereby generating a risk prediction result and a scheduling suggestion plan. The visual display module 14 is coupled to the digital twin module 13 and is configured to simultaneously and visually present the 3D model of the modular cleanroom, the sensing parameter dataset, the contamination risk prediction result, and the scheduling suggestion plan, to provide real-time monitoring and operation for the user. In practice, the 3D model generation module 11, sensing data processing module 12, digital twin module 13, and visual display module 14 of the digital twin system for integrated monitoring of dynamic parameters in the modular cleanroom 1 may be integrated into a computer system, a cloud-based central processing unit, or embedded into an integrated chip.

In this embodiment, the aforementioned equipment may further include cell incubators, biosafety cabinets, centrifuges, shakers, gas supply systems, unmanned vehicles, automated guided vehicles (AGVs), robots, sensor modules, conveyor belts, and automatic controllers, which are used for cell cultivation, production processes, logistics handling, or environmental sensing functions. The facilities may include cleanroom walls, partition panels, air purification devices, airtight doors, lighting systems, heating, ventilation, and air conditioning with filtration systems, pipeline facilities, and floor drainage devices, which together form the basic structure of the modular cleanroom and maintain the cleanliness level and environmental stability of the workspace. In addition, to enhance the intelligent management of overall operations, the digital twin system for integrated monitoring of dynamic parameters in the modular cleanroom 1 in this embodiment can simultaneously integrate the sensing parameters and control commands of AGVs or robots, allowing both the static modular cleanroom and the dynamic AGVs or robots to be managed under a unified, data-driven architecture for intelligent and modular integration. In practical applications, the types and configurations of the equipment and facilities are not limited to the examples listed above and may be selected and adjusted based on the user's actual requirements, production types, and process conditions.

In this embodiment, the dynamic parameters received by the sensing data processing module 12 may further include personnel-related parameters (e.g., entry and exit records, dwell time, and movement trajectories), equipment-related parameters (e.g., operating status, on/off time, and internal environment), material-related parameters (e.g., batch number, expiration date, and storage condition), method-related parameters (e.g., operating procedures, process time, and operation techniques used by operators), and environment-related parameters (e.g., temperature, humidity, pressure differential, particle concentration, and gas composition). However, in practical applications, the types of dynamic parameters are not limited to those listed above and may be expanded or adjusted according to process control objectives and user monitoring requirements.

In this embodiment, the machine learning model may be selected from, but is not limited to, a decision tree model, a support vector machine (SVM), a random forest, a deep neural network (DNN), or a convolutional neural network (CNN), and may be continuously trained and optimized based on the captured parameter data. However, in practical applications, the types and algorithms of the machine learning models are not limited to those mentioned above and may be adjusted according to the characteristics of the training data and the requirements of the prediction tasks.

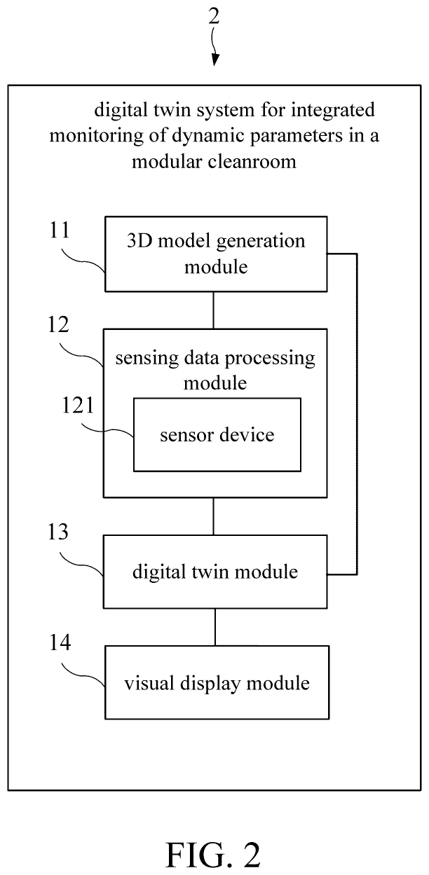

Please refer to FIG. 2, FIG. 2 shows a functional block diagram of a digital twin system for integrated monitoring of dynamic parameters in a modular cleanroom 2 of another embodiment of the present invention. This embodiment differs from the aforementioned embodiments in that the sensing data processing module 12 further comprises at least one sensor device 121. The sensor device 121 may be disposed on the internal structure, facility, or equipment of the cleanroom and configured to detect and receive the aforementioned dynamic parameters in real time, including personnel-related, equipment-related, material-related, method-related, or environment-related real-time information. Through the data input from the sensor device 121, the completeness and timeliness of the sensing parameter dataset can be enhanced, thereby improving the accuracy of contamination risk assessment and scheduling analysis. In practical applications, the installation location of the sensor device 121 is not limited to a specific position, and can be flexibly adjusted and optimally arranged according to the types of parameters to be monitored, equipment operational characteristics, spatial conditions, and measurement requirements to meet the needs of different sites and processes. The sensor device 121 in this embodiment may further include, but is not limited to, a temperature and humidity sensor, a differential pressure sensor, a particle counter, a CO₂ concentration sensor, a volatile organic compound (VOC) sensor, an infrared personnel motion detector, an RFID reader, a weight sensor, a vibration sensor, or a power monitoring module. Please note that other modules, models, and their corresponding functions in the digital twin system for integrated monitoring of dynamic parameters in the modular cleanroom 2 of this embodiment are substantially the same as those described in the previous embodiments and will not be repeated herein.

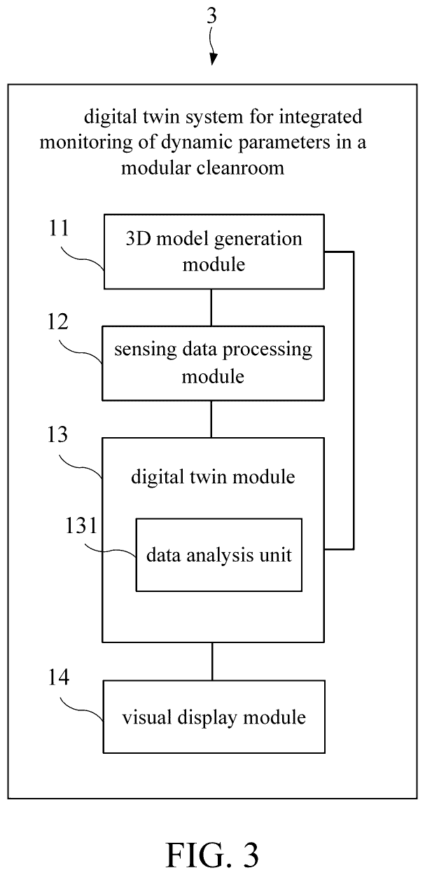

Please refer to FIG. 3, FIG. 3 shows a functional block diagram of a digital twin system for integrated monitoring of dynamic parameters in a modular cleanroom 3 of another embodiment of the present invention. This embodiment differs from the foregoing embodiments in that the digital twin module 13 in this embodiment further comprises a data analysis unit 131. The data analysis unit 131 generates a contamination risk level prediction result, an equipment maintenance prediction result, and a cleanroom environmental quality variation assessment result based on the sensing parameter dataset and historical data. The contamination risk level prediction result can be used to assess the level of contamination risk in the cleanroom or specific operational areas. The equipment maintenance prediction result is generated based on the operational status of the equipment and the trend of abnormal parameters to evaluate its potential failure risk and determine the optimal maintenance timing. The cleanroom environmental quality variation assessment result provides variation trend analysises and quality warnings for critical indicators such as pressure differentials, temperature and humidity, and airflow stability inside the cleanroom.

In practical applications, the data analysis unit 131 can further cooperate with a machine learning model to perform automated training and accurate prediction. By continuously collecting and analyzing the sensing parameter dataset and historical operational data, the accuracy and adaptability of the prediction model can be improved, thereby optimizing the prediction of contamination risk levels and the scheduling recommendations. The contamination risk level prediction result, the equipment maintenance prediction result, and the cleanroom environmental quality variation assessment result generated by the data analysis unit 131 can be immediately fed back to the visual display module 14, enabling the user to monitor the system operational status, contamination risk, and optimal scheduling suggestions in real time, thereby enhancing the overall operational stability and management efficiency of the cleanroom. In addition, the visual display module 14 may further comprise at least one mobile device, wherein the mobile device comprises one of mobile phones, computers, or tablet, and is configured to receive real-time information output from the data analysis unit 131 via a wireless communication module. The user can browse the contamination risk prediction results and scheduling suggestion plans through a human-machine interface of the mobile device in real time, and perform remote operations and control, thereby improving response efficiency, reducing the frequency of personnel entry into the cleanroom, and lowering contamination risk.

In the present embodiment, the machine learning model can be trained based on historical operational data and the sensing parameter dataset. Through data cleaning, normalization, and feature engineering, the data is transformed into input vectors readable by the model. For model construction, the data analysis unit 131 may apply algorithms such as Random Forest, Gradient Boosting Tree, or Long Short-Term Memory (LSTM) to establish classification models that predict contamination risk levels under different cleanroom operating conditions, or to construct regression models for predicting contamination indices. Furthermore, the prediction model can incorporate equipment usage records and maintenance schedules, and apply optimization strategies such as reinforcement learning or evolutionary algorithms to generate scheduling recommendations that minimize contamination risks across production nodes. To improve prediction accuracy and model flexibility, the data analysis unit 131 can implement error feedback learning and incremental learning mechanisms. Under conditions of environmental parameter drift, the system may trigger a model retraining procedure to achieve self-learning and continuous optimization of the prediction model. It should be noted that the other modules, models, and corresponding functions of the digital twin system for integrated monitoring of dynamic parameters in the modular cleanroom 3 in this embodiment are substantially the same as those described in the previous embodiments, and will not be redundantly described herein.

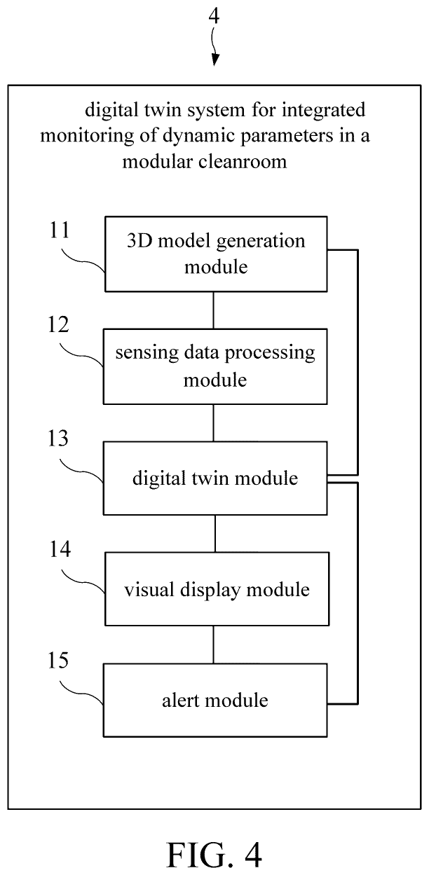

Please refer to FIG. 4, FIG. 4 shows a functional block diagram of a digital twin system for integrated monitoring of dynamic parameters in a modular cleanroom 4 of another embodiment of the present invention. In comparison with the aforementioned embodiments, the present embodiment further differs in that the digital twin system for integrated monitoring of dynamic parameters in the modular cleanroom 4 additionally comprises an alert module 15. The alert module 15 is coupled to the digital twin module 13 and the visual display module 14. The alert module 15 is configured to automatically trigger a visual and audio alarm when any of the following results generated by the data analysis unit 131 exceeds a predefined threshold: the contamination risk level prediction result, the equipment maintenance prediction result, or the cleanroom environmental quality variation assessment result. This allows users to be immediately notified of potential abnormal conditions in the system. In addition, the alert module 15 may also transmit the real-time warning content to the user interface via the visual display module 14, and simultaneously provide a set of corresponding maintenance recommendations to assist the user in promptly adjusting or responding to equipment or cleanroom environmental conditions. This further reduces the risk of potential contamination and production interruptions. It should be noted that the other modules, models, and corresponding functions of the digital twin system for integrated monitoring of dynamic parameters in the modular cleanroom 4 in this embodiment are substantially the same as those described in the previous embodiments, and will not be redundantly described herein.

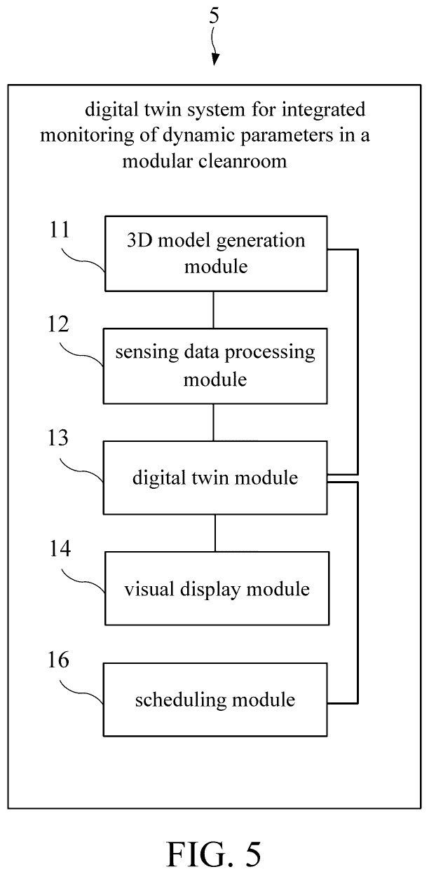

Please refer to FIG. 5, FIG. 5 shows a functional block diagram of a digital twin system for integrated monitoring of dynamic parameters in a modular cleanroom 5 of another embodiment of the present invention. In comparison with the aforementioned embodiments, the present embodiment further differs in that the digital twin system for integrated monitoring of dynamic parameters in the modular cleanroom 5 further comprises a scheduling module 16. The scheduling module 16 is coupled to the digital twin module 13 and is configured to simulate and optimize task scheduling across multiple production lines based on various dynamic parameters, including equipment availability, process sequences, operator behavior, and cleanroom reconfiguration status. Through the scheduling module 16 in the present embodiment, the sensor parameter datasets and the historical production data can be integrated to evaluate dependencies among production units, cross-contamination risks, and resource conflicts, thereby generating an optimized production scheduling plan. Furthermore, the scheduling module 16 may reference the prediction results from the data analysis unit 131 to automatically adjust scheduling sequences and production node arrangements based on the predicted maintenance time of equipment or contamination risk levels. This facilitates intelligent and flexible scheduling management for multiple production lines in the cleanroom and effectively enhances production efficiency and system operational stability. It should be noted that the other modules, models, and corresponding functions of the digital twin system for integrated monitoring of dynamic parameters in the modular cleanroom 5 in this embodiment are substantially the same as those described in the previous embodiments and will not be redundantly described herein.

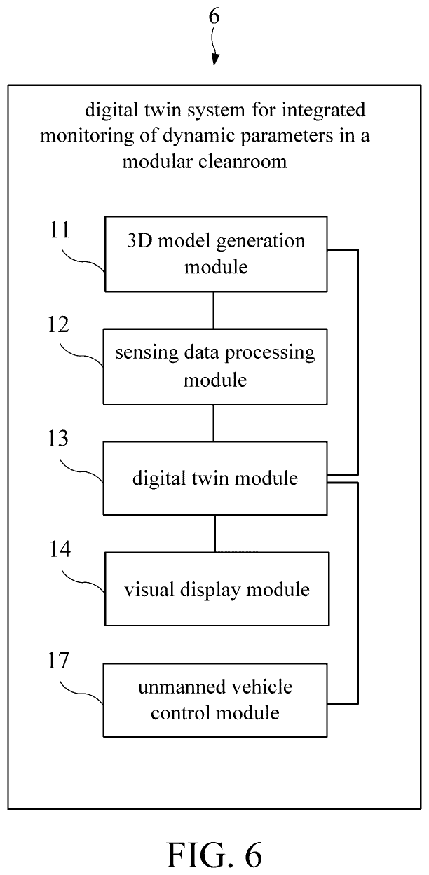

Please refer to FIG. 6, FIG. 6 shows a functional block diagram of a digital twin system for integrated monitoring of dynamic parameters in a modular cleanroom 6 of another embodiment of the present invention. In the present embodiment, the digital twin system for integrated monitoring of dynamic parameters in the modular cleanroom 6 further comprises an unmanned vehicle control module 17. The unmanned vehicle control module 17 is coupled to the digital twin module 13 and is configured to automatically adjust the traveling paths of multiple unmanned vehicles (such as automated guided vehicles, AGVs) based on an optimized routing command generated by the digital twin module 13, so as to avoid contamination hot zones or path overlap areas, thereby reducing the risks of cross-contamination and logistics interference. In this embodiment, the unmanned vehicle control module 17 performs dynamic path planning and real-time rerouting based on the 3D model and real-time sensing parameters. When the system detects an increase in contamination level in a specific area or a high density of personnel movement, it can immediately reassign logistics movement sequences to enhance the operational safety and route fluency of the cleanroom. It should be noted that the other modules, models, and corresponding functions of the digital twin system for integrated monitoring of dynamic parameters in the modular cleanroom 6 of this embodiment are substantially the same as those described in the previous embodiments and will not be redundantly described herein.

In another embodiment, the 3D model generation module 11 is further configured to support the reconfiguration simulation of the modular cleanroom space structure. Based on production conditions, site constraints, and operational requirements input by the user, the module simulates the configuration results of equipment and facilities under different cleanroom combination modes, as well as the corresponding logistics routing and scheduling results. The 3D model generation module 11 can integrate modular structure parameters (such as the quantity of cleanroom walls, fan filter units, and partition panels), equipment dimensions and installation constraints, personnel routes, and logistics paths. These are presented within a 3D visualized model to assist users in evaluating and optimizing spatial layouts, equipment arrangements, and logistics strategies during the system planning stage, thereby significantly improving the efficiency of cleanroom construction and operation.

In one embodiment, the digital twin system for integrated monitoring of dynamic parameters in the modular cleanroom according to the present invention may be applied to a cell factory. The cell factory may further include a plurality of modular cleanrooms, and each of which is composed of multiple partition panels. These partition panels are designed for quick assembly and disassembly to form an internal space and an external area. In this embodiment, each partition panel is a movable panel, allowing the cleanroom to be flexibly configured based on spatial requirements. The internal space of each cleanroom is an airtight area, and a controlled environment is maintained through positive pressure and unidirectional laminar airflow to achieve a specified cleanliness level (e.g., ISO Class 5 to 7). When the cell factory undergoes yearly maintenance, specific equipment servicing, or production rescheduling, the digital twin system for integrated monitoring of dynamic parameters in the modular cleanroom can dynamically adjust the activation and disassembly status of each cleanroom based on the predefined scheduling rules. The user can utilize the visualization interface or the simulation results provided by the digital twin module to identify which cleanroom needs to be suspended or reconfigured. Through the rapid disassembly of the movable partition panels, spatial release or transformation can be completed to meet the requirements of yearly maintenance, equipment servicing, or flexible production capacity adjustment, thereby enhancing the overall flexibility and operational efficiency of the cell factory.

Compared with prior art, the digital twin system for integrated monitoring of dynamic parameters in the modular cleanroom of the present invention can integrate multi-source sensing parameters related to structures, equipment, personnel, and environment of the modular cleanroom. By utilizing the 3D model and the digital twin technology, the system enables real-time mapping of the operational status of the physical cleanroom and simultaneously constructs a virtual model to perform contamination risk simulations and predictive analysises. The digital twin system for integrated monitoring of dynamic parameters in the modular cleanroom of the present invention receives and integrates multiple environmental and equipment dynamic parameters via the sensing data processing module to establish the sensing parameter dataset. It further employs the data analysis module and the machine learning model to perform equipment anomaly predictions, clean zone quality variation assessments, and operation scheduling suggestions, effectively overcoming the limitations of traditional systems that rely solely on point-based monitoring and post-event alerts.

In addition, the digital twin system for integrated monitoring of dynamic parameters in the modular cleanroom of the present invention further addresses the spatial structure and reconfiguration characteristics of the modular cleanroom. A 3D scene model is established to simulate the assembly configuration of the modular cleanroom and the arrangement of equipment based on production requirements. The system also calculates the routing paths of unmanned vehicles (e.g., automated guided vehicles) and personnel, predicts potential contamination risks in overlapping areas, and provides optimized route and workflow planning suggestions. Users can simultaneously observe the 3D model, contamination risk prediction results, and scheduling suggestions through the interface, and perform remote control operations, thereby reducing manual intervention and response time.

Furthermore, the digital twin system for integrated monitoring of dynamic parameters in the modular cleanroom of the present invention can also establish a contamination risk assessment mechanism across multiple cleanrooms. It simulates operational interleaving scenarios among different production lines to predict the probability of cross-contamination, and adjusts the cleanroom configuration and distribution of production nodes based on the simulation results to improve the overall efficiency of space and equipment utilization. Through continuous data accumulation and optimization of the learning model, the system can progressively enhance the accuracy of contamination warnings and the effectiveness of scheduling suggestions, thereby achieving intelligent, modular, and data-driven integrated management of cleanrooms.

Moreover, the digital twin system for integrated monitoring of dynamic parameters in the modular cleanroom of the present invention can effectively integrate existing Manufacturing Execution Systems (MES), Supervisory Control and Data Acquisition (SCADA) systems, and Enterprise Resource Planning (ERP) systems. Through data exchange interfaces (such as OPC UA and RESTful API) or middleware, data bridging and transformation can be performed to construct a unified data architecture. The digital twin system for integrated monitoring of dynamic parameters in the modular cleanroom can acquire cleanroom environmental control and equipment operation status in real time via sensor devices, and combine this with operational information from the MES and ERP systems. This enables vertical integration to the decision-making level for contamination prediction and dynamic scheduling suggestions, effectively overcoming the limitations of traditional systems in terms of insufficient data integration and poor response timeliness.

Overall, the present invention enables simulation and interactive analysis across multiple cleanroom environments through the digital twin module, significantly enhancing the flexibility of modular usage, operational efficiency, and quality stability. It provides an integrated platform for real-time monitoring, decision-making support, and operational optimization, making it well-suited for advanced manufacturing and cell factory automation. This offers an innovative and forward-looking solution to existing cleanroom management systems.

With the detailed description of the above embodiments, it is hoped that the features and spirit of the present invention can be more clearly described, and the scoped of the present invention is not limited by the embodiments disclosed above. On the contrary, the intention is to cover various changes and equivalent arrangements within the scope of the patents to be applied for in the present invention. Therefore, the scope of the patent application for the present invention should be interpreted broadly based on the above description so as to cover all possible changes and equivalent arrangements.

What is claimed is:

1. A digital twin system for integrated monitoring of dynamic parameters in a modular cleanroom, comprising:
a 3D model generation module configured to construct a 3D model of the modular cleanroom and a facility and an equipment disposed within the modular cleanroom, wherein the modular cleanroom comprises a plurality of cleanrooms;
a sensing data processing module coupled to the 3D model generation module, a sensing data processing module configured to receive a plurality of dynamic parameters and generate a sensing parameter dataset;
a digital twin module coupled to the 3D model generation module and the sensing data processing module, configured to simulate the modular cleanroom in real time based on the sensing parameter dataset, execute a contamination risk prediction and a scheduling suggestion based on a machine learning model, and accordingly generate a contamination risk prediction result and a scheduling suggestion plan; and
a visual display module coupled to the digital twin module, configured to visually present the 3D model of the modular cleanroom, the sensing parameter dataset, the contamination risk prediction result, and the scheduling suggestion plan in a visualized and real-time manner for a user monitoring and operation.

2. The digital twin system for integrated monitoring of dynamic parameters in the modular cleanroom of claim 1, wherein the dynamic parameters further comprise a personnel-related parameter, an equipment-related parameter, a material-related parameter, a method-related parameter, and an environment-related parameter.

3. The digital twin system for integrated monitoring of dynamic parameters in the modular cleanroom of claim 1, wherein the sensing data processing module further comprises:
at least one sensor device disposed on at least one of the cleanrooms, the facility, and the equipment, and configured to detect and receive the dynamic parameters in real time.

4. The digital twin system for integrated monitoring of dynamic parameters in the modular cleanroom of claim 1, wherein the digital twin module further comprises:
a data analysis unit configured to generate a contamination risk level prediction result, an equipment maintenance prediction result, and a cleanroom environmental quality variation assessment result based on the sensing parameter dataset and a historical data.

5. The digital twin system for integrated monitoring of dynamic parameters in the modular cleanroom of claim 4, further comprising:
an alert module coupled to the digital twin module and the visual display module, configured to trigger a visual and audio alarm and send a real-time warning to the user via the visual display module along with a maintenance recommendation when any of the contamination risk level prediction result, the equipment maintenance prediction result, and the cleanroom environmental quality variation assessment result generated by the data analysis unit exceeds a predefined threshold.

6. The digital twin system for integrated monitoring of dynamic parameters in the modular cleanroom of claim 1, further comprising:
a scheduling module coupled to the digital twin module, configured to perform a task scheduling simulation and optimization for multiple production lines based on an equipment availability, a process sequence, a personnel operation behavior, and a cleanroom reconfiguration status.

7. The digital twin system for integrated monitoring of dynamic parameters in the modular cleanroom of claim 1, further comprising:
an unmanned vehicle control module coupled to the digital twin module, configured to automatically adjust a travel path of a plurality of unmanned vehicles based on an optimized routing command generated by the digital twin module, so as to avoid a contamination hotspot or a path-overlapping area.

8. The digital twin system for integrated monitoring of dynamic parameters in the modular cleanroom of claim 1, wherein the 3D model construction module is further configured to support the reconfiguration of the modular cleanroom space and to simulate a configuration result of the equipment and the facility, as well as a logistics routing schedule result under different combinations.

9. The digital twin system for integrated monitoring of dynamic parameters in the modular cleanroom of claim 1, wherein the digital twin system for integrated monitoring of dynamic parameters in the modular cleanroom is applied to a cell factory, and each of cleanrooms in the modular cleanroom comprises a plurality of partition panels, the partition panels are configured for rapid assembly to form an internal space and an external area, each of the partition panels is a movable panel, and the internal space of each of the cleanrooms is a sealed space maintained under positive pressure and laminar flow to achieve a predefined cleanliness level.

10. The digital twin system for integrated monitoring of dynamic parameters in the modular cleanroom of claim 9, wherein when the cell factory schedules a yearly maintenance, a repair and maintenance, or a production process, each of the cleanrooms that is designated from the modular cleanrooms is reconfigured by quickly disassembling each of the movable partition panels based on the yearly maintenance, the repair and maintenance, or the production schedule, so as to comply with the yearly maintenance, the repair and maintenance, or the production schedule.
